(19) United States
(12) Patent Application Publication
(10) Pub. No.: US 2026/0262161 A1
(43) Pub. Date: Sep. 3, 2026

(54) Component Carrier and Method of Manufacturing the Same

(71) Applicant: AT&S Austria Technologie & Systemtechnik Aktiengesellschaft, Leoben (AT)

(72) Inventors: Hans PARK, Chongqing (CN); Jeesoo MOK, Leoben (AT); Jeffrey JIANG, Chongqing (CN)

(21) Appl. No.: 19/162,998

(22) PCT Filed: Oct. 5, 2023
(86) PCT No.: PCT/EP2023/077606

§ 371 Date: Sep. 8, 2025

(30) Foreign Application Priority Data
Mar. 8, 2023 (CN) 202310252526.8

(51) Int. Cl. H05K 1/02

(52) U.S. Cl. CPC H05K 1/0271

(57) ABSTRACT

The present application provides a component carrier and a method of manufacturing the same. The component carrier includes a stack having at least one electrically insulating layer structure and at least one electrically conductive layer structure. The stack including an inorganic layer structure, and a reinforcing structure made of crack-inhibiting reinforcing material. The reinforcing structure being provided at least partially at a lateral edge of the inorganic layer structure.

### CROSS REFERENCE TO RELATED APPLICATIONS

This application is a national stage application, filed under 35 U.S.C. § 371, of International Patent Application No. PCT/EP2023/077606, filed on Oct. 5, 2023, claiming priority of the filing date of the Patent Application No. 202310252526.8, filed on Mar. 8, 2023, with the China National Intellectual Property Administration, the disclosures of which are hereby incorporated by reference herein in their entirety.

### TECHNICAL FIELD

The disclosure relates to a component carrier and to a method of manufacturing a component carrier.

### TECHNICAL BACKGROUND

In the context of growing product functionalities of component carriers equipped with one or more components and increasing miniaturization of such components as well as a rising number of components to be connected to the component carriers such as printed circuit boards or component carriers, increasingly more powerful array-like components or packages having several components are being employed, which have a plurality of contacts or connections, with smaller and smaller spacing between these contacts. In particular, component carriers shall be mechanically robust and electrically reliable so as to be operable even under harsh conditions.

Conventional approaches of forming component carriers are still challenging.

### SUMMARY

There may be a need to form a compact and reliable component carrier.

According to an embodiment of the disclosure, a component carrier is provided which comprises a stack comprising at least one electrically insulating layer structure and at least one electrically conductive layer structure, the stack further comprising an inorganic layer structure, and a reinforcing structure comprising or consisting of crack-inhibiting reinforcing material, the reinforcing structure being provided at least partially at a lateral edge of the inorganic layer structure.

According to another embodiment of the disclosure, a method of manufacturing a component carrier is provided, wherein the method comprises providing a stack comprising at least one electrically insulating layer structure and at least one electrically conductive layer structure, further providing the stack with an inorganic layer structure, and forming a reinforcing structure comprising or consisting of crack-inhibiting reinforcing material, the reinforcing structure being provided at least partially at a lateral edge of the inorganic layer structure.

### OVERVIEW OF EMBODIMENTS

In the context of the present application, the term “component carrier” may particularly denote any support structure which is capable of accommodating one or more components thereon and/or therein for providing mechanical support and/or electrical connectivity and/or thermal connectivity. In other words, a component carrier may be configured as a mechanical and/or electronic and/or thermal carrier for components. In particular, a component carrier may be one of a printed circuit board, an organic or inorganic interposer, and an IC (integrated circuit) substrate. A component carrier may also be a hybrid board combining different ones of the above-mentioned and/or other types of component carriers.

In the context of the present application, the term “stack” may particularly denote a flat or planar body. For instance, the stack may be a layer stack, in particular a laminated layer stack or a laminate. Such a laminate may be formed by connecting a plurality of layer structures by the application of mechanical pressure and/or heat. The stack may comprise at least one electrically conductive layer structure and at least one electrically insulating structure. A stack may comprise a plurality of sub-stacks, for example may comprise a first multilayer build-up beneath and a further multilayer build-up above an inorganic layer structure. Preferably, the layers may be aligned parallel within the stack.

In the context of the present application, the term “layer structure” may particularly denote a continuous layer, a patterned layer or a plurality of non-consecutive islands within a common plane. A layer structure may perform the function of providing electrical conductivity and/or electrical insulation.

In the context of the present application, the term “inorganic layer structure” may particularly denote a layer structure which comprises inorganic material, such as an inorganic compound. In particular, dielectric material of the inorganic layer structure or even the entire inorganic layer structure may be made exclusively or at least substantially exclusively from inorganic material. In another embodiment, the inorganic layer structure may comprise inorganic dielectric material and additionally another dielectric material. An inorganic compound may be a chemical compound that lacks carbon-hydrogen bonds or a chemical compound that is not an organic compound. In an example, the inorganic layer structure may comprise glass, for example silicon base glass, in particular soda lime glass, and/or boro-silicate glass and/or alumo-silicate glass and/or lithium silicate glass and/or alkaline free glass. In another example, the inorganic layer structure may comprise ceramic material, for example aluminum nitride and/or aluminum oxide and/or silicon nitride and/or boron nitride and/or tungsten comprising ceramic material. Yet, in another example, the inorganic layer structure may comprise semiconductive material, for example silicon and/or germanium and/or silicon oxide and/or germanium oxide and/or silicon carbide and/or gallium nitride. In a further embodiment, the inorganic layer structure may comprise elemental metal and/or metal alloys, for example, copper and/or tin and/or bronze. Yet in another embodiment, the inorganic layer structure may comprise inorganic material, which is not listed in the above-mentioned examples, such as: MOS₂, CuGaO₂, AgAlO₂, LiGaTe₂, AgInSe₂, CuFeS₂, BeO.

In the context of the present application, the term “reinforcing structure” may particularly denote a physical structure providing the inorganic layer structure with an exterior reinforcement function. The reinforcing structure may provide the inorganic layer structure with additional crack resistance in comparison with a scenario in which the reinforcing structure is absent. More specifically, the reinforcing structure may be configured so that the combination of the inorganic layer structure with the reinforcing structure is less prone to crack than the inorganic layer structure without reinforcing structure.

In the context of the present application, the term “crack-inhibiting reinforcing material” may particularly denote a constituent of the reinforcing structure being specifically adapted for suppressing or even eliminating the risk of crack formation in the inorganic layer structure in the event of mechanical and/or thermal stress. More specifically, the crack-inhibiting reinforcing material, in combination with the position of the resulting reinforcing structure at the lateral edge of the inorganic structure, may absorb and/or repel crack-initiating mechanical load which may be exerted to the component carrier or a preform thereof, preferably during a manufacturing process, in particular during separation of the component carrier from a larger body. For example, the reinforcing structure may comprise reinforcing particles such as reinforcing fibers, for instance glass fibers, which may be embedded in a surrounding matrix of the reinforcing structure. However, it should be mentioned that a structure may be considered as reinforcing structure not or not only due to its material itself, but due to the combination of the material with its specific structural position at the lateral edge of the material of the inorganic layer structure.

In the context of the present application, the term “main surface” of a body may particularly denote one of two largest opposing surfaces of the body or outermost opposing surfaces of the body. The main surfaces may be connected by circumferential side walls. The thickness of a body, such as the inorganic layer structure and/or the reinforcing structure, may be defined by the distance between the two opposing main surfaces.

According to an exemplary embodiment of the disclosure, a crack-suppressing or crack-resistant component carrier is provided which may comprise a layer stack with dielectric and metallic constituents. The stack is also equipped with an inorganic layer structure, such as a glass core. Advantageously, a reinforcing structure having crack-inhibiting reinforcing material is formed at (for example adjacent to, for instance spaced only by a resin-filled gap, or directly on) at least part of a lateral edge of the inorganic layer structure for protecting the latter against cracks which may occur during a manufacturing process and/or during operation of the component carrier. The implementation of an inorganic layer structure (for instance a glass carrier) in a component carrier (for example a printed circuit board or an integrated circuit substrate) may be highly advantageous since this may enable the manufacture of a carrier body with very low surface roughness enabling fine line processing. In addition, an inorganic layer structure (in particular made of glass) may promote the thermal stability of the component carrier by suppressing thermal stress, shrinkage, warpage and delamination. Apart from this, an inorganic layer structure may have excellent high-frequency properties, such as a low Dk and/or Df value. However, an inorganic layer structure (for instance made of glass) may be very brittle and may therefore be very prone to formation of cracks propagating from a lateral edge of the inorganic structure during and after processing a component carrier. Descriptively speaking, cracks may be promoted by mechanical and/or thermal load and may propagate from a lateral edge of an inorganic layer structure into its interior. Hence, cracks may significantly deteriorate the performance of the component carrier and its reliability. The direct or indirect coverage of at least part of an edge of an inorganic layer structure with a reinforcing structure (for instance a tiny piece of FR4) having a crack-reinforcing material (for example glass fibers) may strongly inhibit crack formation and may simultaneously enable the above-mentioned advantageous properties of an inorganic layer structure (such as a glass plate). For example, the inorganic layer structure may be entirely shielded in an interior of the component carrier, and specifically in a lateral direction by the reinforcing structure.

In the following, further embodiments of the component carrier and the method will be explained.

In an embodiment, a thickness of the inorganic layer structure together with a stack build-up may be at least 300 μm. In an embodiment, a thickness of the inorganic layer structure without the stack build-up may be at least 100 μm. For example, a thickness of the inorganic layer structure may be in a range from 500 μm to 1500 μm. Within these specific ranges, it has been tested to be very prone to formation of cracks propagating from a lateral edge of the inorganic structure during and after processing a component carrier.

In an embodiment, the reinforcing structure is a reinforcing frame partially or entirely surrounding the lateral edge of the inorganic layer structure. Preferably, the reinforcing structure is a closed reinforcing frame surrounding the lateral edge of the inorganic layer structure around its entire circumference. A surrounding of the sidewalls of the inorganic layer structure along its entire perimeter by the reinforcing structure may provide an excellent protection against cracks, due to the specific crack-inhibiting material and the position of the reinforcing structure at a lateral edge of the inorganic layer structure, in other words in proximity and/or in contact with the lateral edge. Furthermore, the provision of a reinforcing frame is also properly compatible with a batch manufacture of a plurality of component carriers together (see for instance FIG. 8). In such a configuration, the frame structure may be composed of first beams extending in a first direction and second beams extending in a second direction perpendicular to the first direction, wherein the first beams and the second beams may be integrally formed. Such a configuration may create openings in the frame structure; each opening being delimited by beams along the entire perimeter. In each opening, a corresponding inorganic layer structure may be inserted, and subsequently the individual component carriers may be separated by removing beam material along the first direction and along the second direction.

As an alternative to a frame structure surrounding the inorganic layer structure along its entire perimeter, it is also possible to form a reinforcing structure covering the inorganic layer structure at least at two opposed side walls. This may also provide a certain degree of protection against delamination. In particular, in the preferred embodiments of a rectangular or quadrangular component carrier, two specific opposite sides, due to their dimensions or their different length with respect to the correspondent other sides, can be more prone to crack formation; in that case, it may be possible that only the opposed side walls are associated with the respective reinforcing structure.

In an embodiment, the reinforcing structure forms at least part of an exterior lateral edge of the component carrier. In other words, the reinforcing structure may form at least part of the sidewalls of the component carrier as a whole. Thus, the reinforcing structure may be externally exposed as an exterior sidewall portion of the component carrier. To put it briefly, the reinforcing structure may function as an exterior barrier or buffer against mechanical stress. Such mechanical stress might lead to crack formation when being exerted directly to the inorganic layer structure, i.e. without the protecting reinforcing structure. This is also the result of a streamlined manufacturing procedure where a dummy frame comprising the crack-inhibiting reinforcing material is firstly provided at the lateral edge of the inorganic layer structure, and during the formation of the external profile of the single component carrier a portion of the frame remains in the carrier in the form and with the placement of the reinforcing structure being subject according to embodiments of the disclosure.

In an embodiment, at least part of the lateral edge of the inorganic layer structure and/or at least part of an exterior lateral edge of the component carrier has a tapering sidewall. Such a tapering sidewall may be obtained for example by defining the exterior limits of the inorganic layer structure and/or of the reinforcing structure by laser cutting, a common and easy cutting stage for a component carrier profiling. A tapering or slanted sidewall may further enhance the robustness against cracks, which may be, descriptively speaking, more efficiently reflected by a tapering sidewall. In another embodiment, at least part of the exterior lateral edge of the inorganic layer structure and/or of the reinforcing structure may have a straight sidewall.

In an embodiment, the reinforcing material comprises an organic material. In the context of the present application, the term “organic material” may particularly denote a dielectric material having an organic compound. In particular, the reinforcing structure may be made exclusively or at least substantially exclusively from an organic material. In another embodiment, the reinforcing structure may comprise an organic dielectric material and additionally another dielectric material, for instance providing crack-inhibiting reinforcing particles. An organic compound may be a chemical compound that contains carbon-hydrogen bonds. For example, the organic material may comprise an organic resin material, etc. Use of an organic material may bring the advantage that the physical properties of the reinforcing material are easily adaptable due to the organic material, since there is a huge variety of organic material available.

In an embodiment, the reinforcing material comprises or consists of FR4 material. FR4 material may comprise fully cured resin and glass particles (such as glass fibers or glass spheres) therein. For instance, the reinforcing structure may comprise dielectric material of an organic integrated circuit (IC) substrate or a printed circuit board (PCB). This may lead to the advantage of the combination of the good crack-inhibiting properties of materials with thermal resistance, for example at temperatures higher than 250° C. Use of FR4 material may ensure high quality in terms of spatial orientation of the component carrier constituents inside the component carrier at high thermal load, for example laser treatment and/or lamination.

In particular, FR4 and/or fibrous fillers and/or particle fillers may be used alone or in combination for providing a crack-inhibiting function of a corresponding reinforcing structure. Thus, by a selection or combination of the mentioned and/or other materials, the crack-inhibiting properties of the reinforcing structure may be fine-tuned in accordance with requirements of a specific application. For example, FR4 may comprise glass fibers and glass spheres. This combination shows superior properties regarding crack-inhibition. This material withstands high temperatures above 250° C. However, material having only spheres in a resin matrix may have a lower Young modulus but a higher CTE. Material having only fibers may have a lower CTE but higher Young modulus which makes the material stiffer.

In an embodiment, the reinforcing material comprises reinforcing particles. The reinforcing particles may form the crack-inhibiting reinforcing material and may be specifically selected or adjusted for this purpose. It is possible that the reinforcing particles with a crack-inhibiting function are embedded in a matrix material of the reinforcing structure, such as a resin. In an example, the reinforcing material may comprise particles of different shapes and/or particle sizes, for example in the micrometer (1-1000 μm) and/or nanometer (1-1000 nm) range. Reinforcing particles may impart high reliable reinforcing properties to the reinforcing material. Without wishing to rely upon any theory, the inventors found that reinforcing particles distribute and/or redirect incoming forces, thereby reducing or minimizing crack formation.

In an embodiment, the reinforcing material comprises reinforcing fibers. A fiber may be a thin thread or filament. Fibers of the reinforcing structure may form a distributed and/or interconnected fiber network which increases the mechanical stability and significantly enhances the crack-inhibiting function. Fibers have turned out to be excellent crack-inhibiting reinforcing particles.

In an embodiment, the reinforcing fibers are glass fibers. In particular when the inorganic layer structure is made of glass, forming the crack-inhibiting reinforcing material based on glass as well may be advantageous, since this may reduce a CTE (coefficient of thermal expansion) mismatch between the inorganic layer structure and the reinforcing structure. This may lead, in turn, to improved warpage management and a reduced tendency of undesired delamination of layer structures of the stack. At the same time, glass fibers are mechanically highly robust and have excellent properties in terms of inhibiting propagation of cracks.

In an embodiment, the inorganic layer structure comprises or consists of glass, a ceramic, a semiconductor, or a metal. Thus, appropriate materials for an inorganic layer structure are glass (in particular silicon-based glass), a ceramic (such as aluminum nitride and/or aluminum oxide), and a material comprising a semiconductor (such as silicon oxide, silicon, silicon carbide, gallium nitride, etc.). It is also possible to make the inorganic layer structure of a metallic material, such as copper.

Most preferred is an inorganic layer structure comprising glass or consisting of glass. Such an inorganic layer structure may comprise or consist of silicon dioxide. In particular, the glass layer structure may have glass as main constituent. For example, the glass layer structure may be block-, strip-or plate-shaped. The major material component (in particular the material component of the glass layer structure providing the highest weight percentage) of the glass layer structure is glass, in particular silicon-based glass. For instance, at least 90 weight percent of the glass layer structure may be glass. For example, the glass layer structure may consist only of glass. It is, however, also possible that the glass layer structure comprises one or more additional materials. Advantageously, the glass layer structure may have very flat surfaces so that a planarization stage during processing may be dispensable and fine line processing thereon or above it may be fully supported. Furthermore, the glass layer structure may have a high degree of thermal stability so that thermally caused undesired phenomena such as thermal stress, shrinkage, warpage and delamination will not impact the component carrier significantly. This can make the whole component carrier stable with controllable change of the dimension of the component carrier (such as shrinkage would be less), so the alignment of all elements related to the component carrier may be improved (such as a layer-to-layer alignment, via to pad alignment, pad to via alignment, bump to opening alignment, etc.). Besides that, the coplanarity of components assembled on the component carrier may be improved (such as bumps, capacitors, etc.). Furthermore, a glass material may show a low Dk and low Df behavior with a good dielectric property and may therefore support low loss, high-frequency (in particular improving radio frequency (RF) and high-speed applications as well as high performance computing applications with good signal integrity and low loss. On the other hand, the material in the form of a layer structure, in particular with specific dimensions (i.e. thickness), is very prone to formation of cracks propagating from a lateral edge of the inorganic structure during and after processing a component carrier.

In an embodiment, the inorganic layer structure has at least one through hole filled at least partially with an at least partial metallic filling. The through hole may extend vertically through the entire dielectric layer structure so that the metallic filling may be exposed at one or both opposing main surfaces of the dielectric layer structure. This may enable electricity and/or heat to conduct through the inorganic layer structure by the metallic filling. For example, the metallic filling may comprise a metallic paste and/or a metallic plating structure. For instance, such a metallic paste may be inserted into the at least one through hole and may then be cured by sintering. Concerning plating, a plated metallic structure may be formed in the at least one through hole, for example by sputtering or electroless plating (in particular for forming a seed layer) followed by galvanic plating (for instance for filling the through hole with bulk metal).

The through hole may be filled partially or entirely with a metallic material, such as copper. This may bring the advantage of electrically connecting both exposed surfaces of the component carrier in a short and efficient manner.

In an embodiment, the at least one through hole has an hourglass shape or a continuously tapering state.

In this context, an hourglass shape may be formed by a through hole having two connected tapering sections with inverse tapering directions (compare FIG. 1). Such an hourglass shape may be obtained by forming the respective hole by laser drilling from both opposing main surfaces of the inorganic layer structure.

In alternative embodiments, the respective hole may have a frustoconical shape. Such a continuously tapering shape may be created by laser drilling from only one main surface of the inorganic layer structure.

The hole may then taper towards the side of the inorganic layer structure facing away from the laser source. The provision of through holes in the inorganic layer structure, in particular made through a laser hole-making process, may impart an additional mechanical stress on the thickness of the inorganic layer structure, improving the possibility of the crack formation; the association of the reinforcing structure with the material and placement in accordance with embodiments of the disclosure may decrease or eliminate the possibilities of cracks even if the structure is very prone also due to the through holes passing therethrough.

In an embodiment, the component carrier comprises a component embedded in an accommodation hole of the inorganic layer structure. Such an accommodation hole may particularly denote an opening or via in the inorganic layer structure. Such an accommodation hole may be a through hole extending through the entire inorganic layer structure, may be a blind hole extending into the inorganic layer structure but having a closed bottom, or may be a groove, cavity or recess of any shape. A component, such as an electronic component like a semiconductor chip, may be inserted in the accommodation hole. This may enable an electronic functionality in the component carrier in a compact way. Additionally or alternatively, at least one component, such as at least one electronic component like a semiconductor chip, may be surface mounted on the stack. For example, the accommodation hole is a through hole or is a cavity with closed bottom. On the other hand, the accommodation hole and the respective components may additionally impart a thickness stress on the inorganic layer structure, improving the possibility of the crack formation; the association of the reinforcing structure with the material and placement in accordance with embodiments of the disclosure, may decrease or eliminate the possibilities of such cracks.

In an embodiment, a width of the reinforcing structure is at least 10 μm, for example at least 50 μm. It has turned out that a reinforcing structure having at least the mentioned width values already provides a sufficiently pronounced crack-inhibiting function. In the perspective of improving or even optimizing the space and the compactness of the component carrier considering well-established manufacturing methods about the profiling of the component carrier (for example a dicing or a laser process) from a standard production format (for example 21 inch×24 inch), high quality manufacturing and low scrap ratio may be reached by the use of the aforementioned width of the reinforcing structure.

In an embodiment, a width of the reinforcing structure is not more than 300 μm, for example not more than 150 μm. Advantageously, already a relatively tiny reinforcing structure in accordance with the above-mentioned upper limits may reliably protect the inorganic layer structure against cracks.

Hence, a width of the reinforcing structure at any of the lateral edge portions of the inorganic layer structure may be in particular in a range from 10 μm to 300 μm, in particular in a range from 50 μm to 150 μm. This may ensure that the volume of the inorganic layer structure is significantly larger than the volume of the reinforcing structure while nevertheless ensuring a reliable crack protection. Since the inorganic layer structure may contribute to the actual function of the component carrier while the reinforcing structure is provided only or predominantly for crack protection, it may be preferred to embody the inorganic layer structure as a major constituent and the reinforcing structure as a minor constituent of the entire component carrier. This may be achieved by the mentioned dimensions.

In an embodiment, the component carrier comprises at least one metallic structure directly on at least part of at least one of two opposing main surfaces of the inorganic layer structure. The extremely smooth glass surface of a glass-type inorganic layer structure, for instance having a roughness of less than 50 nm, has the advantage of enabling a fine line pattern in the form of the at least one metallic structure with very small pitch or line space ratio. Thus, direct formation of copper material of the at least one metallic structure on the glass-type inorganic layer structure may enable a high-density integration. In another embodiment, it is possible to form the at least one metallic structure not directly on the glass-type inorganic layer structure but on a dielectric film applied on the glass-type inorganic layer structure. Advantageously, a dielectric film may show very good adhesion even on a very smooth glass-type inorganic layer structure, may therefore provide protection against delamination, and may provide a proper base surface for forming a metallic structure thereon.

In an embodiment, the stack comprises at least one dielectric buffer structure, for example a resin structure, in a lateral gap between the inorganic layer structure and the reinforcing structure. Descriptively speaking, such a dielectric buffer structure in gaps between the inorganic layer structure and the reinforcing structure may function as a mechanical damping structure buffering stress and therefore additionally suppressing crack propagation through the component carrier, and in particular into the inorganic layer structure. The dielectric buffer structure in the gap may bridge a horizontal spacing between an inorganic layer structure and the reinforcing structure. For instance, the width of the gap may be in a range from 10 μm to 150 μm, in particular in a range from 50 μm to 100 μm.

Additionally or alternatively, the stack comprises at least one dielectric buffer structure, for example a resin structure, directly on at least part of at least one of two opposing main surfaces of the inorganic layer structure and/or of the reinforcing structure. To put it briefly, such a horizontally extending dielectric buffer structure on the inorganic layer structure and/or the reinforcing structure may function as a mechanical damping structure buffering stress for further improving mechanical reliability of the component carrier, and in particular of the inorganic layer structure, which may be made of a brittle material such as glass.

Preferably, the dielectric buffer structure mentioned in the preceding paragraphs is free of reinforcing fibers, for example may comprise a fiber-free resin. A corresponding dielectric buffer structure may have excellent mechanical damping properties. For instance, the dielectric buffer structure may be made of a low Young modulus material (in particular having a Young modulus below 15 GPa) and may therefore be soft and elastic for buffering stress in a lateral and/or a vertical direction. Optionally, the dielectric buffer structure may comprise reinforcing spheres (for instance made of glass).

In an embodiment, the stack comprises at least one multilayer build-up on or above at least part of at least one of two opposing main surfaces of the inorganic layer structure and/or of the reinforcing structure. For example, such a multilayer build-up may comprise an electrical wiring structure, a redistribution structure and/or heat dissipating structures. The multilayer build-up may be formed on or above the inorganic layer structure and the reinforcing structure by lamination, i.e. the application of heat and/or pressure. This may bring the advantage of forming complex electrically conductive layer structures in combinations in an easy and well-established manner.

In an embodiment, the stack comprises one multilayer build-up on or above one main surface of the inorganic layer structure and/or of the reinforcing structure and another multilayer build-up on or above another main surface of the inorganic layer structure and/or of the reinforcing structure. In one embodiment, the multilayer build-ups may be asymmetric with respect to each other. Although conventionally, asymmetric multilayer build-ups on two opposing main surfaces of a core or another central carrier structure may be a root cause of warpage and delamination, the provision of a stiff and mechanically robust inorganic layer structure (preferably made of glass) also allows such an asymmetric build-up. This increases the freedom of design of the component carrier designer. Alternatively, the multilayer build-ups may be symmetric with respect to each other.

In an embodiment, a multilayer build-up on one main surface of the inorganic layer structure has a higher integration density of electrically conductive structures than another multilayer build-up on an opposing other main surface of the inorganic layer structure. The term “integration density” may denote a number of electrically conductive structures per area or volume of the respective region of the component carrier. In particular, the amount of contacts (including pads) per area or volume of one multilayer build-up may be higher than the amount of the contacts (including pads) per area or volume on the other multilayer build-up. Thus, integration density may mean a quantity of electrically conductive structures (such as traces) per mm². The integration density above and below the inorganic layer structure can be different. For instance, integration density may be higher at a multilayer build-up facing a surface mounted device (such as a semiconductor chip). Thus, the multilayer build-up of the component carrier having the higher integration density may provide a mounting area for mounting one or a plurality of electronic components such as semiconductor chips.

In an embodiment, a ratio between a volume of the reinforcing structure and a volume of the inorganic layer structure is not more than 5%, for example not more than 2%, preferably not more than 1%. For instance, a ratio between a horizontal width of the reinforcing structure and a horizontal width of the inorganic layer structure is not more than 5%, for example not more than 2%, preferably not more than 1%. Advantageously, even a very tiny reinforcing structure at at least part of an edge of an inorganic layer structure has turned out to be effective for crack-inhibition into a sidewall of the inorganic layer structure. Thus, the vast majority of the central volume of the component carrier may contribute to the functionally active inorganic layer structure. This allows efficient use of the available volume while simultaneously ensuring a high reliability of the component carrier.

In an embodiment, the inorganic layer structure is a core structure. Hence, the inorganic layer structure may form a vertically arranged central support body forming a base for additional organic layer structures on one or both opposing main surfaces thereof. Such a core structure may provide mechanical stability, may contribute to the electrical wiring of the component carrier (in particular for signal transport and/or supply of electric energy), and/or may contribute to heat removal.

In an embodiment, the reinforcing structure extends over an entire vertical (i.e. in a thickness direction of the component carrier) range over which the inorganic layer structure extends. This may bring the advantage that the inorganic layer structure may be protected from mechanical stress, for example from pressure. Mechanical stress may be efficiently distributed over the reinforcing structure and may thereby reduce and/or minimize the crack formation inside the inorganic layer structure during manufacturing stages, for example during lamination. However, it is also possible that the reinforcing structure overlaps with the inorganic layer structure along a vertical direction. Preferably, the reinforcing structure may have a vertical extension corresponding at least to the vertical extension of the inorganic layer structure for optimum crack protection. This may include embodiments in which the upper main surface and/or the lower main surface of the reinforcing structure are vertically aligned with or are flush with the respective main surface of the inorganic layer structure (see for example FIG. 20 or FIG. 21). This may also include embodiments in which the upper main surface and/or the lower main surface of the reinforcing structure protrudes vertically beyond the respective main surface of the inorganic layer structure (see for example FIG. 17 or FIG. 19 to FIG. 21). Furthermore, this may also include embodiments in which the upper main surface and/or the lower main surface of the reinforcing structure are vertically retracted with respect to the respective main surface of the inorganic layer structure (see for example FIG. 18 or FIG. 21). Thus, the embodiments of the disclosure are compatible with very different applications.

In an embodiment, the reinforcing structure comprises a multilayer structure, for example with a symmetric or an asymmetric configuration. The latter configuration can be enabled in particular by embedding a glass layer in the reinforcing structure, which may balance out stress. By configuring the reinforcing structure as a multilayer structure, its properties can be fine-tuned in terms of crack-inhibition, warpage management, suppression of delamination, etc.

In an embodiment, the method comprises forming at least one multilayer build-up on or above at least part of at least one of two opposing main surfaces of the inorganic layer structure and/or of the reinforcing structure before or after assembling the inorganic layer structure with the reinforcing structure. In particular, it may be advantageous to add a build-up of the stack on a glass-type inorganic layer structure before embedding the inorganic layer structure with build-up in a frame-type reinforcing structure. This may simplify the build-up process. However, it is also possible to form the stack both on the inorganic layer structure and on the reinforcing structure after having inserted the inorganic layer structure in a frame-type reinforcing structure.

In an embodiment, the method comprises manufacturing a plurality of component carriers in a batch process by providing a dummy frame comprising crack-inhibiting reinforcing material and having a plurality of openings, inserting a plurality of inorganic layer structures each in an assigned one of the openings, and thereafter separating individual component carriers by removing portions of the dummy frame between adjacent component carriers to thereby form a respective reinforcing structure based on the dummy frame at at least part of a lateral edge of each inorganic layer structure. The described manufacturing process is highly efficient, since it allows the manufacture of a plurality of component carriers simultaneously. This allows the manufacture of the component carriers with high throughput and on an industrial scale.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. In particular a naked die as an example of an electronic component can be surface mounted on a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). A printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in the case of a Chip Scale Package (CSP)). More specifically, a substrate can be understood as a carrier for electrical connections or electrical networks as well as a component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or Interposer may comprise or consist of at least a layer of glass, silicon (Si) and/or a photoimageable or dry-etchable organic material like epoxy-based build-up material (such as epoxy-based build-up film) or polymer compounds (which may or may not include photo-and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, Melamine derivates, Polybenzoxabenzole (PBO), bismaleimide-triazine resin, polyphenylene derivate (e.g. based on polyphenylenether, PPE), polyimide (PI), polyamide (PA), liquid crystal polymer (LCP), polytetrafluoroethylene (PTFE), Bisbenzocyclobutene (BCB) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, titanium and magnesium. Although copper is usually preferred, other materials or coated versions thereof are possible as well, in particular materials coated with supra-conductive material or conductive polymers, such as graphene or poly(3,4-ethylenedioxythiophene) (PEDOT), respectively.

The at least one component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SIC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be surface mounted on the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element.

However, the component may also be an IC substrate, an interposer or a further component carrier, for example in a board-in-board configuration. The component may be surface mounted on the component carrier.

Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

The aspects defined above and further aspects of the disclosure are apparent from the examples of embodiment to be described hereinafter and are explained with reference to these examples of embodiment.

### BRIEF DESCRIPTION OF THE DRAWINGS

FIG. 1 illustrates a cross-sectional view of a component carrier according to an embodiment of the disclosure.

FIG. 2 illustrates a cross-sectional view of a component carrier at an end of a manufacturing process as well as a detailed view of the component carrier according to an embodiment of the disclosure.

FIG. 3 illustrates a side view on a lateral edge of a component carrier according to an embodiment of the disclosure.

FIG. 4, FIG. 5, FIG. 6, and FIG. 7 illustrate cross-sectional views of structures obtained while performing a method of manufacturing a component carrier, shown in FIG. 7, according to an embodiment of the disclosure.

FIG. 8 illustrates a plan view of a preform of a plurality of component carriers manufactured in a batch process according to an embodiment of the disclosure.

FIG. 9 illustrates a cross-sectional view of a component carrier according to an embodiment of the disclosure.

FIG. 10 illustrates different views of structures related to a component carrier manufactured according to an embodiment of the disclosure.

FIG. 11, FIG. 12, FIG. 13, FIG. 14, and FIG. 15 illustrate cross-sectional views of structures obtained while performing a method of manufacturing a component carrier with embedded component, shown in FIG. 15, according to an embodiment of the disclosure.

FIG. 16 illustrates an image of a component carrier according to an embodiment of the disclosure.

FIG. 17, FIG. 18, FIG. 19, FIG. 20, FIG. 21, and FIG. 22 illustrate cross-sectional views of component carriers according to embodiments of the disclosure.

### DETAILED DESCRIPTION OF THE ILLUSTRATED EMBODIMENTS

The illustrations in the drawings are schematically presented. In different drawings, similar or identical elements are provided with the same reference signs.

Before, referring to the drawings, example embodiments will be described in further detail, some basic considerations will be summarized based on which example embodiments of the disclosure have been developed.

In a conventional process of manufacturing a component carrier with glass core, individual component carriers may be separated by dicing or laser cutting through glass. However, this may create undesired cracks propagating into the glass body, as well as undesired chipping. Also, during one or more reflow processes, horizontal cracks may be created in a glass edge. Glass defects may be created by horizontal cracks, curing shrinkage of build-up material, CTE mismatch, etc. Tensile stress of glass may be present in particular along a vertical direction.

According to an embodiment of the disclosure, a component carrier with crack protection has a (preferably laminated) layer stack comprising an inorganic layer structure, for example a glass plate. In addition, a reinforcing structure with a crack-inhibiting reinforcing material (such as fibers inhibiting crack propagation) laterally protects part of or even an entire sidewall of the inorganic layer structure for protecting it from crack formation in the event of stress which may occur for example during separation, for instance by cutting or laser processing, of a component carrier at an end of a manufacturing process. Such a manufacturing process/architecture may synergistically combine the advantageous properties of an inorganic layer structure with a high mechanical reliability of the component carrier. An inorganic layer structure (such as a glass plate) of a component carrier (such as a PCB or an IC substrate) may allow fine line processing in view of its very smooth surface, may be thermally stable, and may provide an excellent high-frequency performance. While the inorganic layer structure alone may be prone to crack formation starting from its sidewall in the event of mechanical stress, protecting at least part of the sidewalls of an inorganic layer structure with a reinforcing structure comprising crack-reinforcing material (for example glass fibers) may protect the inorganic layer structure against cracks and may therefore lead to a highly reliable component carrier.

More specifically, embodiments of the disclosure provide a manufacturing method and a component carrier with a glass core. For example, a component carrier according to an embodiment of the disclosure with glass core may have the same exterior edge as a conventional package substrate. Preferably, the glass body (more generally the inorganic layer structure) of the component carrier is not exposed at the edge of the readily manufactured component carrier. Consequently, a simple dicing process can be used without the risk of crack formation. Accordingly, it is possible to proceed in a simple way during substrate back-end processing and packaging. Since the (preferably glass-type) inorganic structure is not exposed at an exterior surface of the component carrier, there is no risk of mechanical damage (for instance due to deformation, cracking, chipping, etc.). Thus, the obtained component carrier is not prone to damage by horizontal cracks in the glass which may be conventionally created in an exposed glass surface due to thermal stress generated in the reflow process, mechanical stress during separation of the component carrier, etc. It is believed that horizontal cracks in glass may be caused by tensile stress applied in the vertical direction of the glass due to glass defects (such as cracking, chipping) which may be caused by dicing due to a CTE mismatch that occurs in the cooling down after reflow and cure shrinkage of build-up layers. In the case of singulation of component carriers using a laser process to prevent horizontal cracking, there may be a need to prevent carbonization or contamination of the component carrier with foreign particles. In the case of glass, since optical transmittance is excellent, it may be necessary to manage damage of material interfaces (for instance between build-up material and glass) caused by laser penetration. Separation of individual component carriers through material of a reinforcing structure (which may be based for instance on an organic laminate such as FR4) rather than through glass may enable an artifact-free component carrier with excellent protection against lateral crack propagation.

By protecting at least part of the sidewall of an inorganic layer structure (in particular a glass core) by a laterally arranged exterior reinforcing structure (which may be made of a component carrier laminate material), the exterior side wall properties of an organic component carrier may be emulated. More specifically, a glass core structure with the same edge as an organic IC substrate may be obtained. This may prevent an edge of a glass core from experiencing crack creation after dicing, singulation or separation. In particular, this may suppress or even eliminate undesired phenomena such as crack formation, chipping, etc. No issues will occur during a reflow process. The exterior appearance of the obtained component carrier may be the same as that of a conventional component carrier, since the inorganic layer structure may be arranged completely in an interior of the component carrier and will not extend up to an exterior surface of the component carrier. Advantageously, such a component carrier is not prone to mechanical damage (for instance damage caused by cracks, chipping, etc.). In particular, horizontal cracks do not occur in a glass core protected at its exterior side by a reinforcing structure even after multiple reflow processes. In particular, the manufacturing process of embodiments of the disclosure is compatible with a mechanical dicing process and also with a laser cutting process without the need of extensive post-separation treatment or safety measures.

Example embodiments of the disclosure may decrease the manufacturing effort for producing component carriers in comparison with conventional approaches. Advantageously, embodiments of the disclosure may be manufactured using well-known manufacturing equipment without the need of dedicated tools or complex backend processing. In particular, embodiments can solve conventional glass core edge crack issues and may improve the mechanical, thermal and electrical properties of the glass core. The manufacture of component carriers according to embodiments of the disclosure is also compatible with a high layer count when implementing a glass core. Also large dimensions of component carriers, such as 120 mm×120 mm or more, are possible so that an obtainable high flatness and excellent warpage performance may be of utmost advantage. Using an inorganic material such as glass may provide a flat and stiff core enabling a high quality.

Example applications of embodiments of the disclosure relate to component carriers for mobile phones, servers, computing applications, in particular high-performance computing (HPC), and related electronic devices. Also, component carriers having a glass core with an exterior protection by a reinforcing structure may be used for manufacturing flip chip ball grid array (FCBGA) type devices.

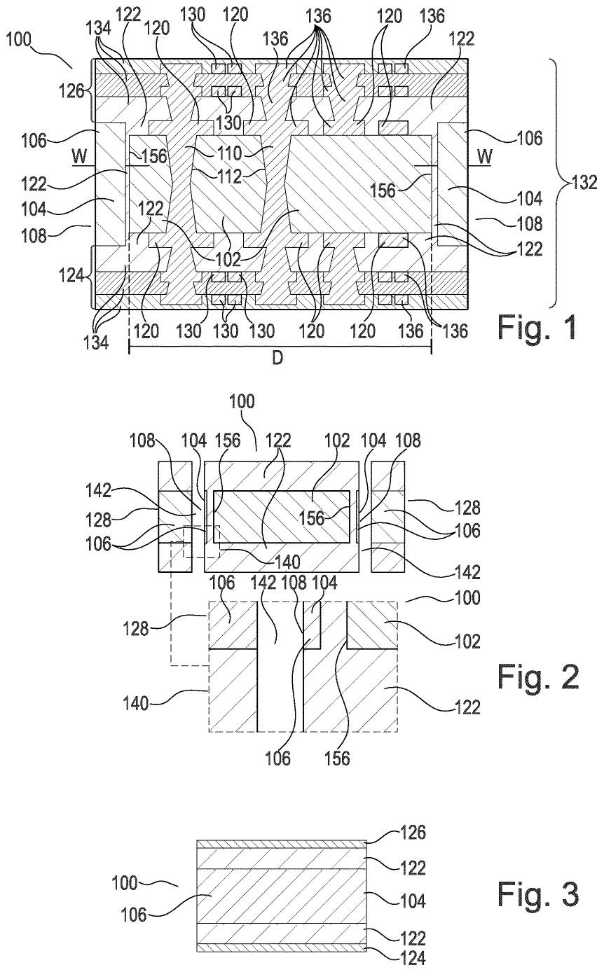

FIG. 1 illustrates a cross-sectional view of a component carrier 100 according to an embodiment of the disclosure. For instance, the component carrier 100 according to FIG. 1 may be embodied as an integrated circuit (IC) substrate or as a printed circuit board (PCB).

The illustrated component carrier 100 comprises a stack 132 having a plurality of electrically insulating layer structures 134 and a plurality of electrically conductive layer structures 136. For example, stack 132 may be a laminated layer stack composed of a lower sub-stack in the form of a lower multilayer build-up 124 and of an upper sub-stack in the form of an upper multilayer build-up 126. The electrically conductive layer structures 136 may comprise patterned copper layers which may form horizontal pads and/or a horizontal wiring structure. Additionally or alternatively, the electrically conductive layer structures 136 may comprise vertical through connections such as copper pillars and/or copper filled laser vias. Moreover, the electrically insulating layer structures 134 may be for example prepreg or resin sheets.

In addition, the stack 132 further comprises a central inorganic layer structure 102 which is here embodied as a glass core or glass plate. The lower multilayer build-up 124 is formed below the inorganic layer structure 102 and the upper multilayer build-up 126 is formed above the inorganic layer structure 102.

Moreover, a reinforcing structure 104 comprising crack-inhibiting reinforcing material 106 is provided at an exterior side of a lateral edge 156 of the inorganic layer structure 102. Hence, sidewalls of inorganic layer structure 102 and reinforcing structure 104 face each other. More specifically, the reinforcing material 106 is arranged adjacent to the lateral edge 156 of the inorganic layer structure 102, separated therefrom only by a gap filled with resin material of a dielectric buffer structure 122. Furthermore, an exterior lateral edge of the reinforcing structure 104 forms part of an exterior lateral edge 108 of the component carrier 100. Although not shown in the cross-sectional view of FIG. 1, the reinforcing structure 104 may surround an entire perimeter of the for example rectangular inorganic layer structure 102 for protecting the latter circumferentially against cracks which might otherwise propagate for instance substantially horizontally into the sidewalls of the inorganic layer structure 102 due to stress during a manufacturing process. For example during a separation process of separating component carrier 100 from a larger compound (for instance by mechanically cutting or by laser cutting), during a reflow process and/or during other manufacturing stages, thermal and/or mechanical load may occur which may damage the inorganic layer structure 102. By the protection of sidewalls of the inorganic layer structure 102 by the reinforcing structure 104, the inorganic layer structure 102 may be reliably protected against cracks, chipping or the like. Thereby, it becomes possible to combine advantageous properties of the glass core-type inorganic layer structure 102 with a high mechanical reliability thanks to the provision of the reinforcing structure 104. By providing a glass-type inorganic layer structure 102 with very low surface roughness on its main surfaces, fine line processing on or above the inorganic layer structure 102 becomes possible. The inorganic layer structure 102 made of glass may also have a positive impact on the thermal stability of the component carrier 100 which may reduce thermal stress, shrinkage-based artifacts, warpage and any tendency of delamination. Furthermore, the glass-type inorganic layer structure 102 may be highly appropriate for high-frequency applications (for instance with frequencies of at least 1 GHz), since glass has a low Dk value which may lead to low losses and high signal integrity.

The reinforcing material 106 of the reinforcing structure 104 may comprise an organic material, such as an epoxy resin. Already such an organic resin may protect the glass material of the inorganic layer structure 102 against horizontally propagating cracks. The reinforcing material 106 may also comprise reinforcing particles, preferably reinforcing glass fibers in a matrix of the above-mentioned resin. A network of glass fibers has turned out as highly efficient for inhibiting propagation of cracks into the glass material of the inorganic layer structure 102. An appropriate choice for the reinforcing material 106 is FR4 material, as commonly used for a core of conventional PCBs. Consequently, the reinforcing structure 104 can be provided with low effort and high benefit.

Still referring to FIG. 1, the inorganic layer structure 102 has a plurality of vertically extending through holes 112 extending through the entire inorganic layer structure 102. The through holes 112 extending side-by-side vertically through the inorganic layer structure 102 may be through glass vias (TGVs). They may be formed in the inorganic layer structure 102 by laser drilling from opposing main surfaces of the inorganic layer structure 102. As a result, the through holes 112 have an hourglass shape composed of two connected tapering sections with opposite tapering directions.

Again referring to FIG. 1, each through hole 112 is filled with a metallic filling 110. The plated metallic filling 110 may comprise solid copper formed by electroless plating or for instance by chemical vapor deposition or physical vapor deposition (for forming a thin seed layer) followed by electroplating (for creating thick bulk copper thereon). The metallic filling 110 extends up to the same vertical level as the inorganic layer structure 102, both at a bottom side and at a top side. By the metallic filling 110, which may be made for example by copper, electric signals may be conducted between the lower multilayer build-up 124 and the upper multilayer build-up 126.

Preferably, a horizontal width, W, of the reinforcing structure 104 may be in a range from 50 μm to 150 μm so that the crack protection can be formed in a compact way. Such a small dimension of the reinforcing structure 104 ensures that the vast majority of the volume between the multilayer build-ups 124, 126 is contributed by the glass material of the inorganic layer structure 102. Preferably, a ratio between a volume of the reinforcing structure 104 and a volume of the inorganic layer structure 102 may be not more than 1%. For example, a ratio between the horizontal width W of the reinforcing structure 104 and a horizontal width D of the inorganic layer structure 102 is not more than 5%, preferably not more than 1% (in this respect, FIG. 1 is only schematic and not true to scale). Thus, the available volume of component carrier 100 may be used highly efficiently while providing at the same time a reliable protection against cracks.

As shown, patterned metallic structures 120 are formed directly on each of two opposing main surfaces of the inorganic layer structure 102. The metallic structures 120 are configured as pads being in direct physical contact with the metallic filling 110 in the inorganic layer structure 102. This allows electricity (in particular signals and/or energy) to conduct vertically through the component carrier 100.

Furthermore, the stack 132 comprises dielectric buffer structures 122, which may be made of epoxy resin structure. The dielectric buffer structures 122 are formed in a lateral gap between the inorganic layer structure 102 and the reinforcing structure 104 as well as directly on both opposing main surfaces of the inorganic layer structure 102 and of the reinforcing structure 104. The dielectric buffer structures 122 may be formed by laminating an at least partially uncured resin sheet below and above the inorganic layer structure 102 and the frame-type reinforcing structure 104. By the lamination process, which may involve mechanical pressure and/or heat, the at least partially uncured resin material may become flowable, may flow into the gap, may start cross-linking or polymerizing, and may then resolidify. As a result, the dielectric buffer structures 122 according to FIG. 1 are obtained. Advantageously, the dielectric buffer structures 122 surround and thereby protect the inorganic layer structure 102 against mechanical load.

According to FIG. 1, the multilayer build-ups 124, 126 are symmetric with respect to each other. However, they may also be asymmetric, since the glass material of the inorganic layer structure 102 provides sufficient robustness and stiffness to avoid excessive warpage and delamination even with an asymmetric configuration of the multilayer build-ups 124, 126. Furthermore, the multilayer build-ups 124, 126 may also comprise fine line structures 130 having a smaller pitch than other electrically conductive layer structures 136 of stack 132. The formation of fine line structures 130, for example having a line space ratio in a range from 2 μm/2 μm to 10 μm/10 μm, in particular 5 μm/5 μm is possible above the inorganic layer structure 102. This is in particular possible when the inorganic layer structure 102 is made of glass, thanks to the pronounced smoothness of such a glass body.

As shown, the reinforcing structure 104 extends over an entire vertical range over which the inorganic layer structure 102 extends and even protrudes vertically beyond the inorganic layer structure 102 at a bottom side and at a top side. This shields the inorganic layer structure 102 properly and therefore contributes as well to the inhibition of cracks.

FIG. 2 illustrates, at a top side, a cross-sectional view of a component carrier 100 at an end of a manufacturing process as well as, in detail 140, a detailed view of part of the component carrier 100 according to an embodiment of the disclosure.

During the manufacturing process, the glass body forming the inorganic layer structure 102 may be inserted in a hole inside of a dummy frame 128 which may be made of FR4. Two resin layers may be laminated on top and on bottom of the obtained structure to thereby form the dielectric buffer structure 122. Thereafter, a separation process may be executed for separating the component carrier 100 from the dummy frame 128. This may be accomplished for example by mechanically cutting along sawing streets or separation lines 142 (or alternatively by laser cutting, not shown). As a result, material of the dummy frame 128 is removed and component carrier 100 is separated. Advantageously, there is no need to cut through the glass material of the inorganic layer structure 102 during separation. The separation process is executed so that the lateral side wall or lateral edge 108 of the obtained component carrier 100 is formed partly by the reinforcing structure 104 (which is a remaining part of the dummy frame 128) and partly by the dielectric buffer structure 122 (see FIG. 3). The glass-type inorganic layer structure 102 remains entirely embedded inside of the component carrier 100 without being exposed to an environment. Consequently, the glass-type inorganic layer structure 102 is properly protected against cracks and other mechanical impact. In the obtained component carrier 100, inorganic layer structure 102 forms a first inner core, and reinforcing structure 104 may form a (for example organic) second outer core.

FIG. 3 illustrates a side view on a lateral edge 108 of a component carrier 100 according to an embodiment of the disclosure.

Hence, FIG. 3 illustrates a sidewall of a component carrier 100 showing crack-inhibiting reinforcing material 106 of an FR4-type reinforcing structure 104. The glass-type inorganic layer structure 102 is not exposed and therefore not visible in FIG. 3. This glass material is protected by the reinforcing structure 104 and by material of the dielectric buffer structure 122.

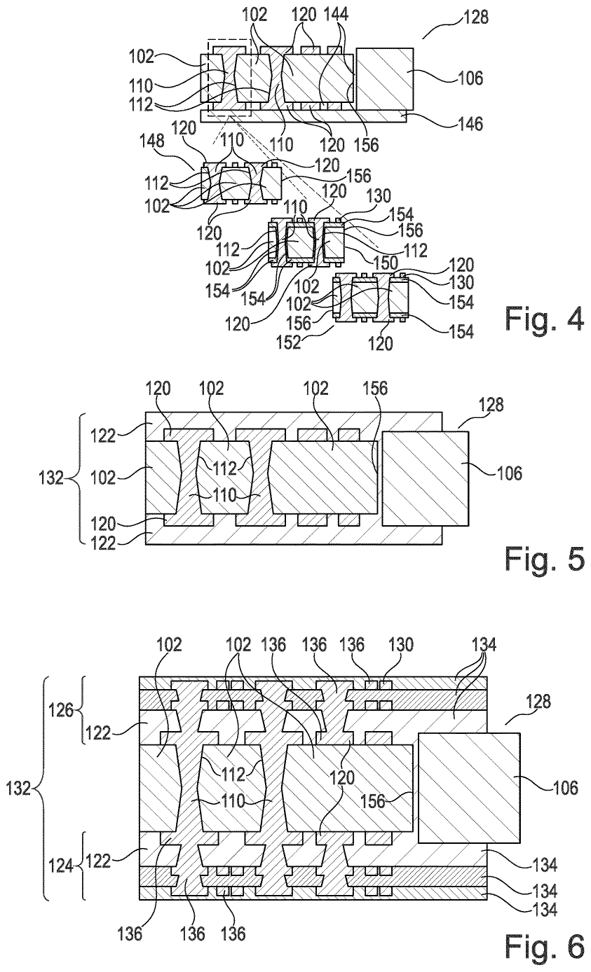

FIG. 4 to FIG. 7 illustrate cross-sectional views of structures obtained while performing a method of manufacturing a component carrier 100, shown in FIG. 7, according to an embodiment of the disclosure.

FIG. 4 illustrates a cross-sectional view of a preform of a component carrier 100 with different options of through-hole filling according to different embodiments of the disclosure.

Referring to the uppermost image of FIG. 4, an inorganic layer structure 102 having a plurality of vertical through holes 112 filled with a metallic filling 110 and being provided with pad-type metallic structures 120 on both opposing main surfaces of the inorganic layer structure 102 is shown. The inorganic layer structure 102 is arranged in a through-hole type opening 144 of a dummy frame 128 formed of a crack-inhibiting reinforcing material 106, such as FR4 . The arrangement is located on a temporary carrier 146, which may be a tape applied by lamination.

Reference signs 148, 150, 152 show three different embodiments of the metallic filling 110 in the through holes 112 (embodied as through glass vias, TGV) of the inorganic layer structure 102: Referring to reference sign 148, the through holes 112 may be entirely filled with the metallic filling 110, for instance by a combination of electroless plating and electroplating. Referring to reference sign 150, the through holes 112 as well as the two opposing main surfaces of the inorganic layer structure 102 may be covered with a resin layer 154, and a remaining volume of the through holes 112 may then be filled with the metallic filling 110, for instance by a combination of electroless plating and electroplating. Referring to reference sign 152, the through holes 112 may be entirely filled with the metallic filling 110, for instance by a combination of electroless plating and electroplating, wherein the two opposing main surfaces of the inorganic layer structure 102 may be covered with a resin layer 154 before forming the metallic structures 120 on the resin layer 154. Example embodiments of the disclosure may be realized with any of the three alternatives according to reference signs 148, 150, 152. The manufacturing process will be described in the following referring to alternative 148 but can be executed correspondingly according to reference signs 150, 152.

Referring to FIG. 5, stack 132 is provided with dielectric buffer structures 122 above and beneath the metallized inorganic layer structure 102 and also filling a gap between the inorganic layer structure 102 and the dummy frame 128. This may be accomplished by laminating an initially at least partially uncured resin sheet on top of the structure shown in FIG. 4, wherein the resin material becomes at least partially cured by pressure and/or increased temperature and also flows in the gaps. Thereafter, the temporary carrier 146 may be removed. After that, a further initially at least partially uncured resin sheet may be laminated onto the bottom of the obtained structure, wherein the resin material becomes at least partially cured by pressure and/or increased temperature and may also flow in possibly remaining unfilled portions of the gaps. As a result, the dielectric buffer structure 122 is obtained which surrounds the inorganic layer structure 102 laterally as well as on top and on bottom.

In order to obtain the structure shown in FIG. 6, the stack 132 is provided on top and bottom of the structure of FIG. 5 with a plurality of electrically insulating layer structures 134 (for instance prepreg sheets and a solder resist at a respective exterior surface) and a plurality of electrically conductive layer structures 136 (for example patterned metal layers and metal-filled laser vias). As a result, a respective multilayer build-up 124, 126 is obtained above both opposing main surfaces of the inorganic layer structure 102 and of the dummy frame 128. Additionally or alternatively to the solder resist, also a surface finish may be formed at an exterior surface of the obtained structure.

In order to obtain the component carrier 100 according to FIG. 7, the structure of FIG. 6 may be subjected to a separation process which may comprise mechanically cutting or dicing through dielectric stack material 122, 134 and through dummy frame 128 along separation lines 142. No cutting through metallic material 120, 136 or glass of the inorganic layer structure 102 is necessary. This avoids the formation of cracks and accelerates the separation process. Alternatively to a mechanical separation process, separation may also be accomplished by laser cutting. As shown, the separation through dummy frame 128 may be executed asymmetrically in a horizontal direction, so that only a very thin section of dummy frame 128 remains connected at the lateral edge 108 of component carrier 100, thereby forming reinforcing structure 104 of crack-inhibiting reinforcing material 106 protecting a lateral edge 156 of the inorganic layer structure 102. This crack protection can be achieved by covering a sidewall or lateral edge 156 of the glass of inorganic layer structure 102 with resin of dielectric buffer structure 122 and the latter with FR4 core material in the form of reinforcing structure 104. Although not visible in the cross-sectional view of FIG. 7, the entire perimeter of the inorganic layer structure 102 may be covered with resin of dielectric buffer structure 122 and may be surrounded with the reinforcing structure 104 made of crack-inhibiting material 106.

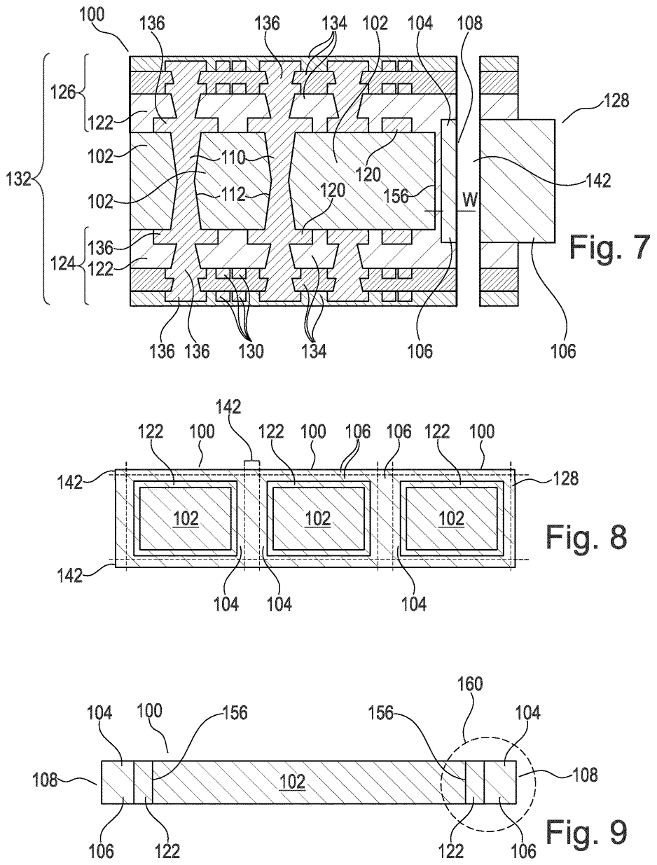

FIG. 8 illustrates a plan view of a preform of a plurality of component carriers 100 manufactured in a batch process according to an embodiment of the disclosure.

For manufacturing a plurality of component carriers 100 in a batch process, a dummy frame 128 is provided which may be made of crack-inhibiting reinforcing material 106 (such as FR4) and which has a plurality of openings, each for accommodating a respective inorganic layer structure 102. Although FIG. 8 shows a one-dimensional linear array of openings in dummy frame 128, also a two-dimensional arrangement of openings in dummy frame 128 is possible, for instance in a matrix-like fashion in rows and columns (not shown). Thereafter, each of a plurality of inorganic layer structures 102 is inserted in an assigned one of the openings. After that, dielectric buffer structure 122 may be formed in lateral gaps between the respective inorganic layer structure 102 and the dummy frame 128, and optionally also above and below the structure of FIG. 8 (i.e. perpendicular to the paper plane of FIG. 8, not shown).

Thereafter, the individual component carriers 100 may be separated from the integral structure shown in FIG. 8 by removing portions of the dummy frame 128 between adjacent component carriers 100. By this separation along separation lines 142, a respective reinforcing structure 104 is formed at a respective circumferentially closed lateral edge 156 of a respective inorganic layer structure 102, i.e. entirely surrounding each inorganic layer structure 102. In other words, the reinforcing structure 104 of each component carrier 100 can be a circumferentially closed reinforcing frame surrounding the lateral edge 156 of the inorganic layer structure 102 around its entire circumference. As a result, two materials, i.e. resin of dielectric buffer structure 122 and crack-inhibiting material 106 of reinforcing structure 104 protect the glass edge of inorganic layer structure 102.

FIG. 9 illustrates a cross-sectional view of a component carrier 100 according to an embodiment of the disclosure. Such a component carrier 100 may be obtained by separation from the integral structure shown in FIG. 8. Region 160 of component carrier 100 according to FIG. 9 shows a double layer protection structure composed of resin of dielectric buffer structure 122 on lateral edge 156 of glass-type inorganic layer structure 102 and crack-inhibiting material 106 covering exterior sidewalls of the dielectric buffer structure 122 for protecting inorganic layer structure 102. The double layer protection structure protects the inorganic layer structure 100 against mechanical impact, and in particular against the formation of cracks and chipping.

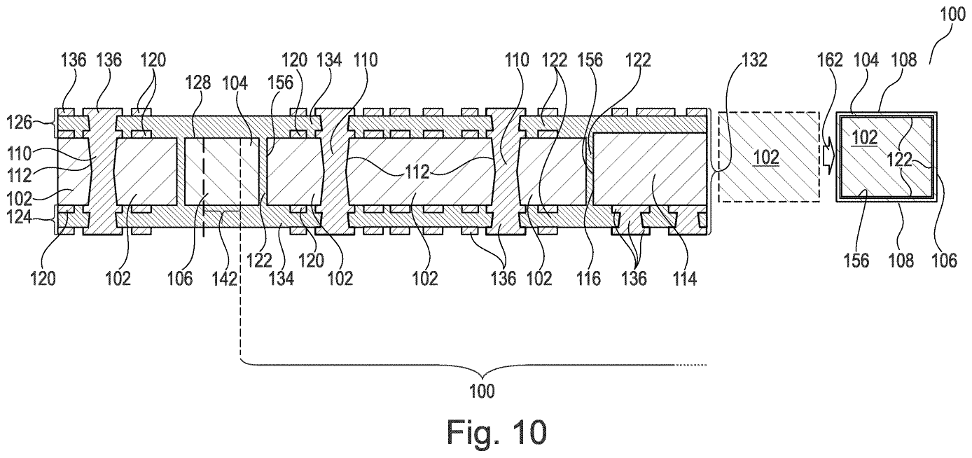

FIG. 10 illustrates different views of structures related to a component carrier 100 manufactured according to an embodiment of the disclosure.

The main image of FIG. 10 illustrates that component carrier 100 comprises a component 114 which is embedded in an accommodation hole 116 of the inorganic layer structure 102. For example, component 114 may be an electronic component such as a semiconductor die.

Embedding the component 114 in the inorganic layer structure 102 of glass is a very compact solution. A lateral gap between the component 114 and the inorganic layer structure 102 may be filled as well by resin of dielectric buffer structure 122. Electrically conductive pads of component 114 may be interconnected in component carrier 100 by electrically conductive layer structures 136.

In the design of FIG. 10, the provision of reinforcing structure 104 made of crack-inhibiting reinforcing material 106 for protecting a lateral edge 156 of the inorganic layer structure 102 leads only to a very minor reduction of the glass area portion of component carrier 100. For example, and as illustrated by a transition arrow 162, the glass area portion may be decreased only by 0.9% (i.e. from 100% to 99.1%) by providing the double protection structure composed of gap-filling dielectric buffer structure 122 and reinforcing structure 104.

Advantageously, the gap-filling dielectric buffer structure 122 is in direct physical contact with both the lateral edge 156 of the inorganic layer structure 102 and an interior lateral edge of the reinforcing structure 104. In other words, the gap-filling dielectric buffer structure 122 laterally bridges the lateral edge 156 of the inorganic layer structure 102 and the interior lateral edge of the reinforcing structure 104.

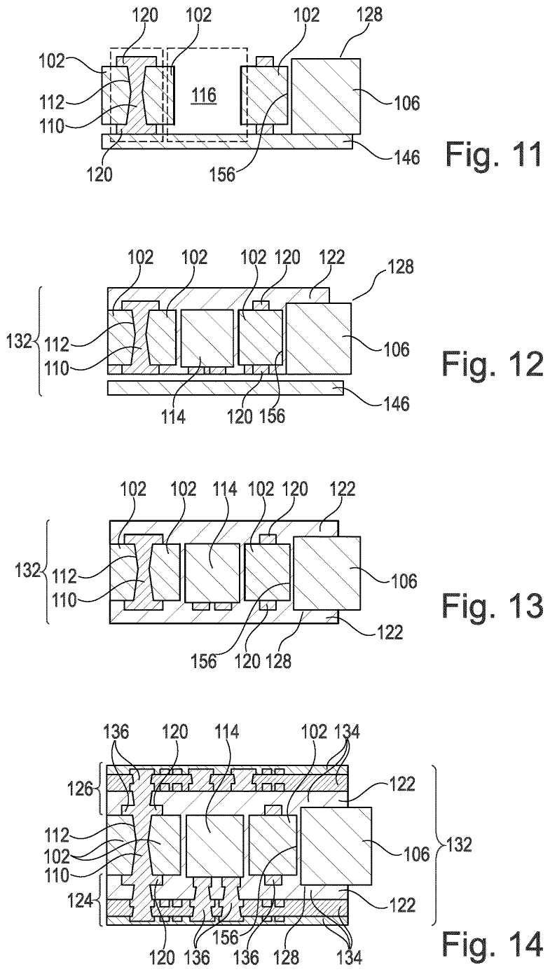

FIG. 11 to FIG. 15 illustrate cross-sectional views of structures obtained when performing a method of manufacturing a component carrier 100 with embedded component 114, shown in FIG. 15, according to an embodiment of the disclosure.

Referring to FIG. 11, a structure is shown which corresponds to the structure of FIG. 4, wherein, according to FIG. 14, an accommodation hole 116 is formed as a through hole extending vertically through inorganic layer structure 102. Although not shown, it is alternatively possible to configure accommodation hole 116 as a cavity with closed bottom, the closed bottom being formed by material of inorganic layer structure 102.

In order to obtain the structure according to FIG. 12, a component 114 (for instance a semiconductor die) is inserted in the accommodation hole 116 of the inorganic layer structure 102. A first part of dielectric buffer structure 122 may then be formed by laminating on the top side a dielectric sheet comprising an at least partially uncured resin, thereby covering the top side and filling at least part of the gaps between inorganic layer structure 102 and component 114 as well as between inorganic layer structure 102 and dummy frame 128. The temporary carrier 146 may then be removed.

Referring to FIG. 13, a second part of dielectric buffer structure 122 may then be formed by laminating on the bottom side a further dielectric sheet comprising initially an at least partially uncured resin, thereby covering the bottom side and optionally filling at least part of an optionally remaining empty part of the gaps between inorganic layer structure 102 and component 114 as well as between inorganic layer structure 102 and dummy frame 128.

Referring to FIG. 14, multilayer build-ups 124, 126 may then be formed on top and bottom of the structure shown in FIG. 13, as described above referring to FIG. 6.

Referring to FIG. 15, component carrier 100 may then be separated by removing material of dummy frame 128 and of dielectric layer structure 134 along separation lines 142.

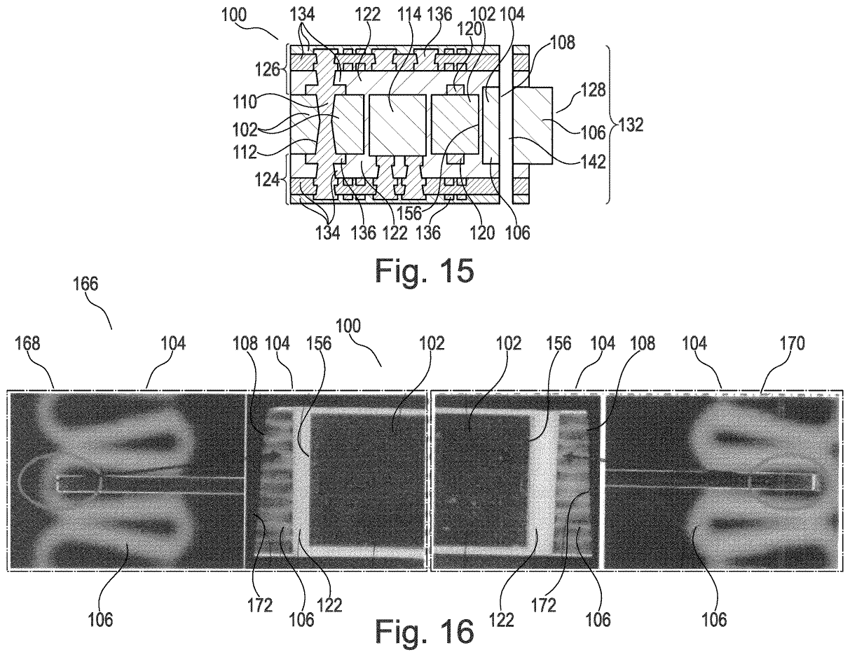

FIG. 16 illustrates an image 166 of a component carrier 100 according to an embodiment of the disclosure.

The central portion of the image 166 of FIG. 16 shows a glass-type inorganic layer structure 102 surrounded by resin material of dielectric buffer structure 122. Lateral edges 156 of inorganic layer structure 102 are laterally spaced with respect to reinforcing structure 104 only by a tiny gap filled with resin of dielectric buffer structure 122. Lateral edges 156 of inorganic layer structure 102 are protected by reinforcing structure 104 against cracks. As shown in details 168, 170 of image 166, crack-inhibiting reinforcing material 106 of reinforcing structure 104 comprises glass fibers.

As shown in FIG. 16, the exterior lateral edge 108 of reinforcing structure 104 and also of component carrier 100 has a tapering sidewall 172. Such an exterior tapering sidewall 172 may provide a further protection of inorganic layer structure 102 against horizontal cracks. For instance, such a tapering sidewall 172 may be achieved by separating component carrier 100 by laser processing. It is also possible that a lateral edge 156 of glass-type inorganic layer structure 102 is formed by laser processing, which may also lead to a tapering sidewall.

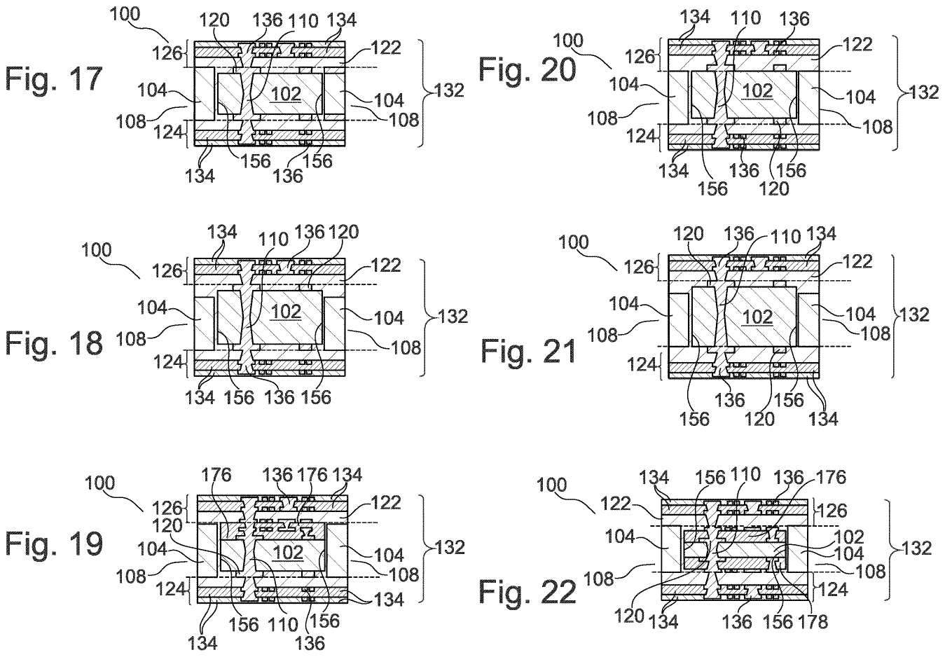

FIG. 17 to FIG. 22 illustrate cross-sectional views of component carriers 100 according to embodiments of the disclosure. These embodiments substantially correspond to the embodiments of FIG. 1. In the following, only differences of the embodiments of FIG. 17 to FIG. 22 will be explained.

Referring to FIG. 17, the reinforcing structure 104 extends over an entire vertical range over which the inorganic layer structure 102 extends. More specifically, the upper main surface and the lower main surface of the reinforcing structure 104 protrude vertically beyond the respective main surface of the inorganic layer structure 102. A surface of a copper structure on the inorganic layer structure 102 is flush with the reinforcing structure 104 on the left-hand side and copper on outer opposing surfaces of reinforcing structure 104 on the right-hand side.

Referring to FIG. 18, the reinforcing structure 104 overlaps with the inorganic layer structure 102 along a vertical direction. More specifically, the upper main surface of the reinforcing structure 104 is vertically retracted with respect to the upper main surface of the inorganic layer structure 102. Furthermore, the lower main surface of the inorganic layer structure 102 is vertically retracted with respect to the lower main surface of the reinforcing structure 104. At the bottom side, the surface of a copper structure on the inorganic layer structure 102 is flush with the reinforcing structure 104. At the top side, the inorganic layer structure 102 is protruding beyond the reinforcing structure 104.

Referring to FIG. 19, the reinforcing structure 104 extends over an entire vertical range over which the inorganic layer structure 102 extends. More specifically, the upper main surface and the lower main surface of the reinforcing structure 104 protrude vertically beyond the respective main surface of the inorganic layer structure 102. At a bottom side, a surface of a copper structure on the inorganic layer structure 102 is flush with the reinforcing structure 104. At a top side, one or more build-up layers 176 on the inorganic layer structure 102 and a surface of copper in the one or more build-up layers 176 is flush with the reinforcing structure 104.

Referring to FIG. 20, the reinforcing structure 104 extends over an entire vertical range over which the inorganic layer structure 102 extends. More specifically, the upper main surface of the reinforcing structure 104 is vertically aligned with the upper main surface of the inorganic layer structure 102. Thus, the upper main surface of the inorganic layer 102 is flush with the upper main surface of the reinforcing structure 104. Furthermore, the inorganic layer structure 102 is thinner than the reinforcing structure 104 in stack thickness direction.

Referring to FIG. 21, the reinforcing structure 104 extends only over part of the inorganic layer structure 102 along a vertical direction. More specifically, the lower main surface of the reinforcing structure 104 is vertically aligned with the lower main surface of the inorganic layer structure 102. While the lower main surface of the inorganic layer structure 102 is flush with the lower main surface of the reinforcing structure 104, the inorganic layer structure 102 is thicker than the reinforcing structure 104 in stack thickness direction.

Referring to FIG. 22, the reinforcing structure 104 extends over an entire vertical range over which the inorganic layer structure 102 extends. More specifically, the upper main surface and the lower main surface of the reinforcing structure 104 protrude vertically beyond the respective main surface of the inorganic layer structure 102. At a bottom side, a surface of copper on one or more build-up layers 178 on the inorganic layer structure 102 is flush with the reinforcing structure 104. At a top side, a surface of copper on one or more build-up layers 176 on the inorganic layer structure 102 is flush with the reinforcing structure 104.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

1. A component carrier comprising:
a stack comprising at least one electrically insulating layer structure and at least one electrically conductive layer structure, the stack further comprising:
an inorganic layer structure; and
a reinforcing structure comprising or consisting of crack-inhibiting reinforcing material, the reinforcing structure being provided at least partially at a lateral edge of the inorganic layer structure.

2. The component carrier according to claim 1, wherein the reinforcing structure is a reinforcing frame partially or entirely surrounding the lateral edge of the inorganic layer structure.

3. The component carrier according to claim 1, wherein the reinforcing structure forms at least part of an exterior lateral edge of the component carrier.

4. The component carrier according to claim 1, wherein at least part of the lateral edge of the inorganic layer structure and/or at least part of an exterior lateral edge of the component carrier has a tapering sidewall.

5. The component carrier according to claim 1, wherein the reinforcing material comprises an organic material.

6. The component carrier according to claim 1, wherein the reinforcing material comprises reinforcing fibers.

7. The component carrier according to claim 1, wherein the inorganic layer structure comprises or consists of glass, a ceramic, a semiconductor, or a metal.

8. The component carrier according to claim 1, wherein the inorganic layer structure has at least one through hole filled at least partially with an at least partially metallic filling,
wherein the at least one through hole has an hourglass shape or a continuously tapering state.

9. (canceled)

10. The component carrier according to claim 1, comprising a component embedded in an accommodation hole of the inorganic layer structure.

11. The component carrier according to claim 1, wherein a width of the reinforcing structure is at least 10 μm.

12. The component carrier according to claim 1, wherein a width of the reinforcing structure is not more than 300 μm.

13. The component carrier according to claim 1, comprising at least one metallic structure directly on at least part of at least one of two opposing main surfaces of the inorganic layer structure.

14. The component carrier according to any of claim 1, the stack comprising at least one dielectric buffer structure in a lateral gap between the inorganic layer structure and the reinforcing structure.

15. The component carrier according to claim 1, the stack comprising at least one dielectric buffer structure directly on at least part of at least one of two opposing main surfaces of the inorganic layer structure and/or of the reinforcing structure.

16. The component carrier according to claim 1, the stack comprising at least one multilayer build-up on or above at least part of at least one of two opposing main surfaces of the inorganic layer structure and/or of the reinforcing structure.

17. The component carrier according to any of claim 1, wherein a ratio between a volume of the reinforcing structure and a volume of the inorganic layer structure is not more than 5.

18. The component carrier (100) according to claim 1, wherein a ratio between a horizontal width of the reinforcing structure and a horizontal width of the inorganic layer structure is not more than 5.

19. The component carrier according to claim 1, further comprising at least one of the following features:
wherein the inorganic layer structure is a core structure;
wherein the reinforcing structure extends over an entire vertical range over which the inorganic layer structure extends;
wherein the reinforcing structure overlaps with the inorganic layer structure along a vertical direction;
wherein the reinforcing structure comprises a multilayer structure.

20.-22. (canceled)

23. A method of manufacturing a component carrier wherein the method comprises:
providing a stack comprising at least one electrically insulating layer structure and at least one electrically conductive layer structure,
further providing the stack with an inorganic layer structure and forming a reinforcing structure comprising or consisting of crack-inhibiting reinforcing material, the reinforcing structure being provided at least partially at a lateral edge of the inorganic layer structure.

24. The method according to claim 19, further comprising at least one of the following features:
wherein the method comprises forming at least one multilayer build-up, on or above at least part of at least one of two opposing main surfaces of the inorganic layer structure and/or of the reinforcing structure before or after assembling the inorganic layer structure with the reinforcing structure;
wherein the method comprises manufacturing a plurality of component carriers in a batch process by:
providing a dummy frame comprising crack-inhibiting reinforcing material and having a plurality of openings;
inserting a plurality of inorganic layer structures each in an assigned one of the openings; and
thereafter separating individual component carriers by removing portions of the dummy frame between adjacent component carriers to thereby form a respective reinforcing structure based on the dummy frame at at least part of a lateral edge of each inorganic layer structure.

25. (canceled)
